(19) United States
(12) Patent Application Publication
(10) Pub. No.: US 2017/0012237 A1
(43) Pub. Date: Jan. 12, 2017

(54) A FLEXIBLE DISPLAY APPARATUS AND AN ENCAPSULATION METHOD THEREOF

(71) Applicant: BOE TECHNOLOGY GROUP CO., LTD., Beijing (CN)

(72) Inventors: Tao Sun, Beijing (CN); Weifeng Zhou, Beijing (CN); Jing Gao, Beijing (CN)

(21) Appl. No.: 14/435,740

(22) PCT Filed: Jul. 28, 2014
(86) PCT No.: PCT/CN2014/083118

§ 371 Date: Apr. 14, 2015

(30) Foreign Application Priority Data
Apr. 2, 2014 (CN) 201410131612.4

(51) Int. Cl. H01L 51/52; H01L 51/56; H01L 51/00

(52) U.S. Cl. CPC H01L 51/5253; H01L 51/0097; H01L 51/5237; H01L 51/56; H01L 27/326

(57) ABSTRACT

The disclosure describes a flexible display apparatus and an encapsulation method thereof, which are capable of solving the problem of easily producing cracks with the existing encapsulating film layer and improving the performance of flex resistance of the flexible display apparatus. The flexible display apparatus according to the disclosure comprises: an LED device, and a protective layer arranged on a cathode of the OLED device, wherein the protective layer comprises a water oxygen barrier region and a multi-functional region, the multi-functional region has dual functions of a water oxygen barrier and stress blocking, and the thickness of the film layer in the multi-functional region is less than that of the film layer in the water oxygen barrier region, and/or the film texture in the multi-functional region is looser than that in the water oxygen barrier region.

### FIELD OF THE INVENTION

The disclosure relates to the field of display, and in particular, to a flexible display apparatus and an encapsulation method thereof.

### BACKGROUND OF THE INVENTION

The development of traditional flat panel display device technologies has become increasingly mature, whereas flexible display devices are about to become the mainstream in the display field by virtue of their characteristics of being light & thin, bendable, and impact resistant. Therein, OLEDs (Organic Light Emitting Diodes) have become one of the hot spots researched in the field of flexible display recently due to having the excellent performances of a rapid response speed, a wide viewing angle, high luminance, low power consumption, being self-luminous, and flex resistance, etc.

An OLED device is very sensitive to water vapor and oxygen, and it is prone to decay. An effective encapsulation may prevent immersion of the water vapor and oxygen, prevent the organic materials from ageing, and prolong the lifetime of the OLED device. Nowadays, for a flexible OLED, there are mainly two encapsulation ways, the cover plate encapsulation and the thin film encapsulation (TFE), wherein the cover plate encapsulation uses a prefabricated cover plate for encapsulation, predominantly glass materials and film materials; and the thin film encapsulation mainly adopts a single layer of thin film or multiple layers of thin film for encapsulation.

FIG. 1 shows a schematic diagram of encapsulating a flexible display apparatus in the prior art. After the manufacture of a cathode of an OLED device 12 on a flexible substrate 11 is finished, a protective layer 13 is produced first for covering the cathode of the OLED device 12, and then a protective film 14 is attached on the protective layer 13. Therein, it is mainly the protective layer 13 that plays the role of encapsulation, and prevents the immersion of the water vapor and oxygen; the protective film 14 is mainly used for preventing the protective layer 13 from being scratched. The inventors have found that there is generally the following problem with the existing encapsulation methods: when the flexible display device is bent, the encapsulating film layer (i.e., the protective layer 13) is easy to crack, leading to a poor performance of flex resistance of the flexible display apparatus.

### SUMMARY OF THE INVENTION

The inventors have studied deeply the problem with the encapsulation of the flexible display device in the prior art, and found the cause for the appearance of the above-mentioned problem: when the flexible display device is bent, the encapsulating film layer is easily caused to crack along the defect locations, owing to small holes present in the encapsulating film layer and the problem with the stress matching between the encapsulating film layer and a film layer it contacts with. The above-mentioned defect locations refer to the pinholes of the film layer produced at the time of coating, or the micro-cracks due to a poor stress between the film layers, and when the flexible display device is bent, these locations are the points of stress concentration, and are easily affected by an external force to crack.

Based on the above finding of the inventors, the disclosure provides a flexible display apparatus and an encapsulation method thereof, which can solve the problem of easily producing cracks with the existing encapsulating film layer, thereby improving the performance of flex resistance of the flexible display apparatus.

According to an aspect of the disclosure, there is provided a flexible display apparatus comprising: an LED device, and a protective layer arranged on a cathode of the OLED device, the protective layer comprising a water oxygen barrier region and a multi-functional region, the multi-functional region having dual functions of a water oxygen barrier and stress blocking, wherein the thickness of the film layer in the multi-functional region is less than that of the film layer in the water oxygen barrier region, and/or the film texture in the multi-functional region is looser than that in the water oxygen barrier region.

Since the protective layer in the flexible display apparatus according to the disclosure comprises a multi-functional region, when the flexible display apparatus is bent, the stress of the film layer resulting from bending of the film layer gets buffered in the multi-functional region, that is, the existence of the multi-functional region may cut off the expansion path of the stress of the film layer, and thereby may reduce the possibility of producing micro-cracks at the time of bending; meanwhile, the existence of the multi-functional region may further block the expansion of the cracks. As a result, the performance of flex resistance of the device is improved.

In an embodiment of the flexible display apparatus according to the to disclosure, the location of the multi-functional region corresponds to a spaced area between adjacent pixels, and the location of the water oxygen barrier region corresponds to a pixel area. Since the film layer corresponding to the multi-functional region varies in texture, thickness and degree of looseness, this may affect the overall optical transmittance of the flexible display is apparatus. Therefore, the location of the multi-functional region may correspond to a spaced area between adjacent pixels so as to avoid that the visual effect of the flexible display apparatus is affected.

In an embodiment of the flexible display apparatus according to the disclosure, the protective layer comprises: a first continuously distributed protective layer and a second patterned protective layer, wherein the first protective layer covers the cathodes of all the OLED devices, and the second protective layer is only distributed in the water oxygen barrier region, or preferably, distributed in a corresponding area over a pixel. In the corresponding area over a pixel are arranged the first protective layer and the second protective layer, the film layer is relatively thick and is a water oxygen barrier region; whereas in a spaced area between adjacent pixels is only arranged the first protective layer, namely, the film layer in a spaced area between adjacent pixels is relatively thin, and forms the multi-functional region, such that the stress and cracks within the encapsulating film layer may be blocked here when bent. Generally, the thickness of the first protective layer is 0.05-1 μm.

In an embodiment of the flexible display apparatus according to the disclosure, the texture of one of the first protective layer and the second protective layer is the silicon-nitrogen-based material or the silicon-oxygen-based material, or the textures of both the first protective layer and the second protective layer are the silicon-nitrogen-based material or the silicon-oxygen-based material.

In an embodiment of the flexible display apparatus according to the disclosure, the protective layer comprises: a first film layer with a dense film texture, only distributed in the water oxygen barrier region or especially distributed in a corresponding area over a pixel; and a second film layer with a loose film texture, only distributed in the multi-functional region or especially distributed in a gap between the first film layers. Therein, the film texture of the second film layer is looser than that of the first film layer and formed by coating at different steps, and there is no continuity between the distribution areas of the second film layers, such that expansion of stress may be cut off, and therefore the stress and cracks within the encapsulating film layer are blocked here. Hence, the distribution area of the second film layer corresponds to a multi-functional region, whereas the film texture of the first film layer is relatively dense, and its distribution area corresponds to a water oxygen barrier region.

In an embodiment of the flexible display apparatus according to the disclosure, the first film layer is of the silicon-nitrogen-based material or the silicon-oxygen-based material with a dense film texture; and the second film layer is of the silicon-nitrogen-based material or the silicon-oxygen-based material with a loose film texture.

According to another aspect of the disclosure, there is provided an encapsulation method for a flexible display apparatus, the encapsulation method comprising: after the completion of a cathode of an OLED device, forming a protective layer comprising a water oxygen barrier region and a multi-functional region overlying the cathode of the OLED device, wherein the multi-functional region has dual functions of a water oxygen barrier and stress blocking, and the thickness of the film layer in the multi-functional region is less than that of the film layer in the water oxygen barrier region, and/or the film texture in the multi-functional region is looser than that in the water oxygen barrier region. The encapsulation method solves the problem of easily producing cracks with the existing encapsulating film layer, and improves the performance of flex resistance of the flexible display apparatus by arranging a multi-functional region in the protective layer to cut off the expansion path of the stress of the film layer and the path for crack expansion.

In an embodiment of the encapsulation method for a flexible display apparatus according to the disclosure, the step of forming a protective layer comprising a water oxygen barrier region and a multi-functional region overlying the cathode of the OLED device may comprise: forming a first protective layer continuously distributed and completely covering the cathode of the OLED device on the cathode of the OLED device; and forming a second protective layer only distributed in a corresponding area over a pixel on the first protective layer, wherein an area where the second protective layer is located constitutes the water oxygen barrier region, whereas an area in which only the first protective layer is distributed (or a corresponding area over a spacing between adjacent pixels) constitutes the multi-functional region. Generally, on the first protective layer, the second protective layer may be formed in a corresponding area over a pixel by using a mask plate.

In an embodiment of the encapsulation method for a flexible display apparatus according to the disclosure, the step of forming a protective layer comprising a water oxygen barrier region and a multi-functional region overlying the cathode of the OLED device may comprise: forming a first film layer with a dense film texture in a corresponding area over a pixel on the cathode of the OLED device; and forming a second film layer with a loose film texture in a gap between the first film layers, wherein an area where the first film layer is located constitutes the water oxygen barrier region, whereas an area where the second film layer is located constitutes the multi-functional region.

### BRIEF DESCRIPTION OF THE DRAWINGS

In order to more clearly illustrate the technical solutions in embodiments of the disclosure, the appended drawings needing to be used in the embodiments will be introduced briefly in the following. Obviously, the drawings in the following description are only some embodiments of the disclosure, and for those of ordinary skills in the art, other drawings may also be obtained according to these drawings under the premise of not paying out creative work.

FIG. 1 shows a schematic diagram of the encapsulation of a flexible display apparatus in the prior at;

FIG. 2 shows a schematic diagram of the location distribution of a multi-functional region on a protective layer in a flexible display apparatus according to an embodiment of the disclosure;

FIG. 3 shows a schematic diagram of the encapsulation of a flexible display apparatus according to a first embodiment of the disclosure;

FIG. 4 shows a schematic diagram of the encapsulation of a flexible display apparatus according to a second embodiment of the disclosure;

FIG. 5 shows a flow chart of an encapsulation method for the flexible display apparatus according to the first embodiment of the disclosure; and

FIG. 6 shows a flow chart of an encapsulation method for the flexible display apparatus according to the second embodiment of the disclosure;

### REFERENCE NUMERALS

10 Substrate ;11 Flexible substrate ;12 OLED device ;13 Protective layer ; 14 Protective film ; 15 Pixel ; 120 Water oxygen barrier region ; 130 Multi-functional region ; 131 First protective layer ; 132 Second protective layer ; 134 First film layer ; 135 Second film layer.

### DETAILED DESCRIPTION OF THE INVENTION

In the following the technical solutions of the disclosure will be described clearly in detail in connection with the drawings.

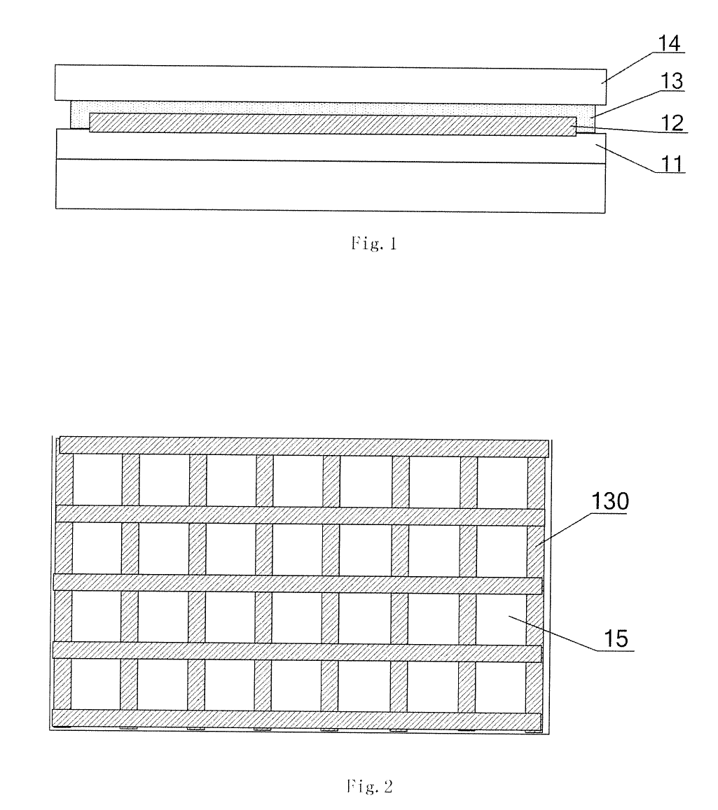

As described above, FIG. 1 shows a schematic diagram of the encapsulation of a flexible display apparatus in the prior at. As shown in the figure, the encapsulation structure of the flexible display apparatus comprises, in turn from bottom to top, a flexible substrate 11; an OLED device 12; a protective layer 13 completely covering the cathode of the OLED device 12; and a protective film 14 covering the protective layer 13. Therein, the protective layer 13 mainly plays the role of encapsulation to prevent immersion of water and oxygen; the protective film 14 is mainly used for preventing the protective layer 13 from being scratched. The existing encapsulation structure has the following problem: when the flexible display device is bent, the encapsulating film layer (i.e., the protective layer 13) is easy to crack, leading to a poor performance of flex resistance of the flexible display apparatus.

With respect to the above problem with the encapsulation structure of the flexible display apparatus in the prior art, the inventors have found by research the source of the problem, that is: when the flexible display device is bent, the encapsulating film layer is easily caused to crack along the defect locations, owing to small holes present in the encapsulating film layer and the problem with the stress matching between the encapsulating film layer and a film layer it contacts with. Based on the above research, the stress resulting from the bending of the OLED device 12 may be blocked by arranging a multi-functional region, so as to avoid that the protective layer 13 produces cracks. The basic idea is that, the film layer of the multi-functional region may be arranged with a smaller thickness or a looser film texture, to facilitate that the stress of the film layer resulting from the bending of the film layer gets buffered in the multi-functional region to cut off the expansion path of the stress of the film layer, such that the possibility of micro-cracks of the protective layer 13 caused by the bending of the OLED device 12 may be reduced, and the expansion of the cracks may be blocked, hence improving the performance of flex resistance of the device.

As compared to the prior art, the main innovation point of the encapsulation structure of a flexible display apparatus according to the disclosure lies in that the protective layer 13 as shown in FIG. 1 has been changed. In particular, the protective layer in the encapsulation structure of the flexible display apparatus according to an embodiment of the disclosure comprises a water oxygen barrier region and a multi-functional region, wherein the multi-functional region having dual functions of a water oxygen barrier and stress blocking, the thickness of the film layer in the multi-functional region is less than that of the film layer in the water oxygen barrier region, and/or the film texture in the multi-functional region is looser than that in the water oxygen barrier region.

FIG. 2 shows a schematic diagram of the location distribution of a multi-functional region 130 on a protective layer in a flexible display apparatus according to an embodiment of the disclosure. In the flexible display apparatus according to a embodiment the disclosure, the thickness and the degree of looseness of the film texture of the film layer in the multi-functional region 130 may be designed according to the actually required performance of flex resistance. In addition, the size, shape and location of the multi-functional region 130 may also be designed according to the actual needs. However, since the film layer corresponding to the multi-functional region 130 varies in texture, thickness and degree of looseness, this affects the overall optical transmittance of the flexible display apparatus. Therefore, as shown in FIG. 2, the location of the multi-functional region 130 may correspond to a spaced area between adjacent pixels so as to avoid that the visual effect of the flexible display apparatus is affected.

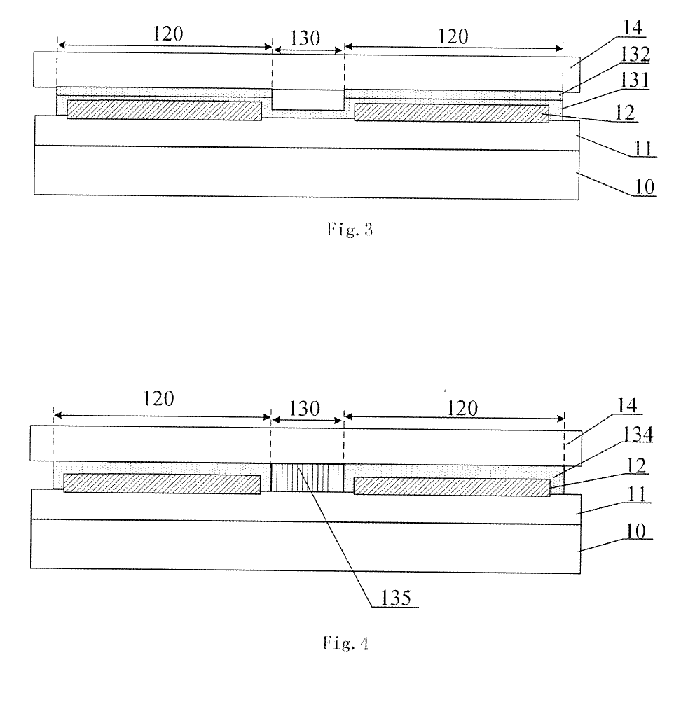

As regards to the particular construction of the protective layer, for example, the following several ways may be adopted: a first way in which it may be that a single layer film is arranged at the preset location of the multi-functional region 130, and a dual-layer film is arranged in the remaining region (the preset location of the water oxygen barrier region), such that the thickness of the film layer at the preset location of the multi-functional region 130 is relatively small to form the multi-functional region 130, and the remaining region forms the water oxygen barrier region; a second way in which it may be that a first film layer with a relative loose film texture is formed at the preset location of the multi-functional region 130 so as to form the multi-functional region 130, whereas a second film layer which is relative dense is formed in the remaining region (the preset location of the water oxygen barrier region) so as to form the water oxygen barrier region; and a third way in which it may be that a protective film layer is first formed as a whole (e.g., a water oxygen barrier protective layer is formed utilizing an encapsulation approach in the prior art), then the film layer is etched at the preset location of the multi-functional region 130, after which the thickness of the film becomes smaller or the film texture becomes looser at the preset location, thereby forming the multi-functional region 130, whereas other un-etched areas form the water oxygen barrier regions. Of course, when implemented particularly, the protective layer may also be constructed to employing any other appropriate methods, and in the procedure of constructing the protective layer, the specific thickness of the film layer or the specific degree of looseness of the film texture in the multi-functional region 130 may be set according to the actual needs (e.g., the requirement for the performance of flex resistance or other factors) and the specific material. In the following, the construction of the protective layer (especially the multi-functional region therein) of the flexible display apparatus according to the disclosure will be described in particular with reference to FIG. 3 and FIG. 4.

FIG. 3 shows a schematic diagram of the encapsulation of a flexible display apparatus according to a first embodiment of the disclosure, wherein the protective layer corresponds to the first way of construction in the above. As shown in FIG. 3, on a substrate 10 is a flexible substrate 11, on the flexible substrate 11 are arranged an OLED device 12 and a circuit driving the OLED device 12, thereon is arranged a protective layer for encapsulation, and on the protective layer is arranged a protective film 14, which protective film 14 is mainly used for preventing the protective layer from being scratched. As shown in the figure, the protective layer comprises a first protective layer 131 which is continuously distributed and a second protective layer 132 which is patterned, wherein the first protective layer 131 completely covers a cathode of the OLED device 12 to prevent the immersion of water and oxygen, and the second protective layer 132 is only distributed in a corresponding area over a pixel.

As shown in FIG. 3, in a corresponding area over a pixel are arranged the first protective layer 131 and the second protective layer 132, the film layer is relatively thick, and the area where it is located forms a water oxygen barrier region 120; whereas in a corresponding area over a spacing between adjacent pixels is only arranged the first protective layer 131, namely, the film layer in a corresponding area over a spacing between adjacent pixels is relatively thin, and the area where it is located forms a multi-functional region 130, such that the stress and cracks within the encapsulating film layer may be blocked here when bent. It needs to be noted that in FIG. 3, the water oxygen barrier region 120 and the multi-functional region 130 only relate to the partition of the protective layer (comprising the first protective layer 131 and the second protective layer 132), and are not related with other devices (like the protective film 14, the OLED device 12, etc.) of the flexible display apparatus. In particular, the water oxygen barrier region 120 only indicates an area where the second protective layer 132 is located, and the multi-functional region 130 indicates an area where only the first protective layer 131 is distributed.

It may be appreciated that the thinner the thickness of the above first protective layer 131, the better its performance of flex resistance, but its corresponding sealing effect will also drop, and therefore the thickness of the first protective layer 131 should be appropriated to take into account both the sealing effect and the performance of flex resistance. For example, the thickness may be 0.05-1 μm.

The texture of one of the first protective layer 131 and the second protective layer 132 may be the silicon-nitrogen-based material (e.g. silicon nitride) or the silicon-oxygen-based material (e.g., silicon oxide). Or the textures of both the first protective layer 131 and the second protective layer 132 may be the silicon-nitrogen-based material or the silicon-oxygen-based material. Therein, the silicon-nitrogen-based material comprises for example a material containing silicon and oxygen, such as silicon nitride, and the silicon-oxygen-based material comprises for example a material containing silicon and nitrogen, such as silicon oxide.

The embodiment as shown in FIG. 3 provides a construction way for the protective layer, may reduce the probability of the encapsulating film layer producing cracks, and improve the performance of flex resistance of the device; moreover, it does not need to improve the existing preparation flow and thus is easily implemented. When the protective layer is prepared specifically, it is only necessary to prepare the original protective layer with a single layer film structure respectively by dividing it into two steps, i.e., forming a dual-layer film structure, wherein the first layer of film, i.e., the first protective layer 131, is distributed continuously, which is the same as the existing preparation approach; and the second layer of film, i.e., the second protective layer 132, is only distributed in a corresponding area over a pixel, and in preparation, a mask plate may be used for occlusion, or the photolithography may be used to form a pattern.

FIG. 4 shows a schematic diagram of the encapsulation of a flexible display apparatus according to a second embodiment of the disclosure, wherein the protective layer corresponds to the second way of construction in the above. The differences between the encapsulation structure of FIG. 4 and that of FIG. 3 lie in that in FIG. 4, the protective layer comprises: a first film layer 134 with a dense film texture distributed in a corresponding area over a pixel, i.e., a water oxygen barrier region 120; and a second film layer 135 with a loose film texture distributed in a gap between the first film layers 134 or in an area corresponding to a spacing between adjacent pixels, i.e., a multi-functional region 130. It needs to be noted that in FIG. 4, the water oxygen barrier region 120 and the multi-functional region 130 only relate to the partition of the protective layer (comprising the first film layer 134 and the second film layer 135), but are not related with other devices (like the protective film 14, the OLED device 12, etc.) of the flexible display apparatus. In particular, the water oxygen barrier region 120 only indicates an area where the first film layer 134 is located, and the multi-functional region 130 only indicates an area where the second film layer 135 between adjacent water oxygen barrier regions 120 is located.

In the protective layer in the embodiment as shown in FIG. 4, the film texture of the second film layer 135 is looser than that of the first film layer 134 and formed by coating at different steps, and there is no continuity between the distribution areas of the second film layers 135, such that expansion of stress may be cut off, and therefore the stress and cracks within the encapsulating film layer are blocked here. Hence, the distribution area of the second film layer 135 is just a multi-functional region 130, whereas the film texture of the first film layer 134 is relatively dense, and its distribution area is just a water oxygen barrier region 120. It needs to be noted that, although its film texture is loose, the second film layer 135 still needs to be able to provide the basic water oxygen barrier function for the underlying cathode of the OLED device 12.

The first film layer 134 may be of the silicon nitride or the silicon-oxygen-based material with a dense film texture; and the second film layer 135 may be of the silicon nitride or the silicon-oxygen-based material or other porous material with a loose film texture.

In the procedure of preparation, a desired pattern may be obtained by using a mask plate for occlusion or photolithography. In addition, it needs to be noted that, the above-described first film layer 134 and the second film layer 135 may be of the same material, or also may be of different materials. If they are of the same material, the first film layer 134 and the second film layer 135 should be prepared respectively employing different processes (or the same process with different process parameters) to meet different demands for the film textures, and reduce the difference in the film thickness between the water oxygen barrier region 120 and the multi-functional region 130, since an excessively large difference in the film thickness between these two regions will cause adverse affects on subsequent processes for manufacturing the flexible display apparatus.

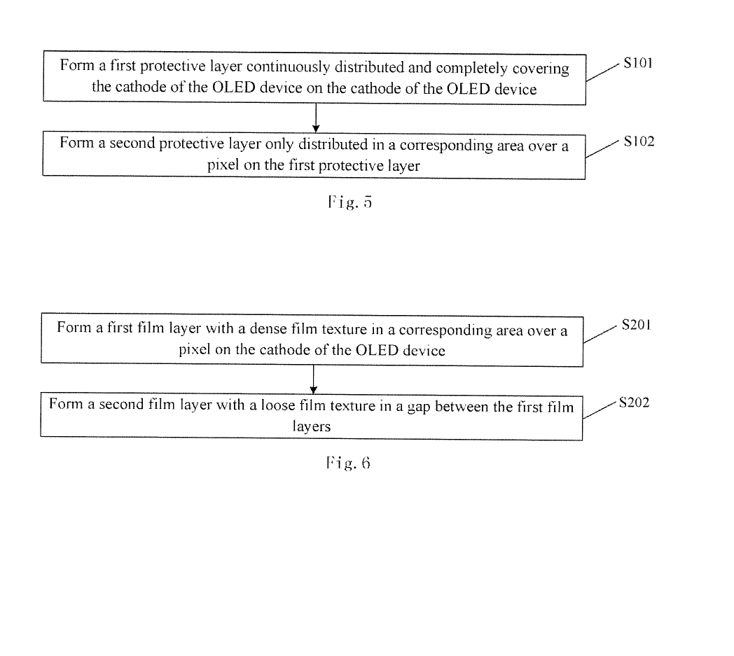

FIGS. 5 and 6 show flow charts of an encapsulation method for the flexible display apparatus according to different embodiments of the disclosure, respectively. The encapsulation methods as shown in FIGS. 5 and 6 may be summarized as follows: after the completion of a cathode of an OLED device, forming a protective layer comprising a water oxygen barrier region and a multi-functional region overlying the cathode of the OLED device, wherein the multi-functional region has dual functions of a water oxygen barrier and stress blocking, the thickness of the film layer in the multi-functional region is less than that of the film layer in the water oxygen barrier region, and/or the film texture in the multi-functional region is looser than that in the water oxygen barrier region. The difference between the two encapsulation methods lies in that since the construction of the protective layer is different, the specific steps of forming it are also different.

FIG. 5 shows a flow chart of an encapsulation method for the flexible display apparatus according to the first embodiment of the disclosure, which to corresponds to the encapsulation structure of the flexible display apparatus as shown in FIG. 3. The encapsulation method comprises: at step S101, forming a first protective layer 131 continuously distributed and completely covering the cathode of the OLED device 12 on the cathode of the OLED device 12; and at step S102, forming a second protective layer 132 only distributed in a corresponding area over a pixel on the first protective layer 131. Therein, an area where the second protective layer 132 is located is a water oxygen barrier region 120, whereas an area in which only the first protective layer 131 is distributed is a multi-functional region 130.

For the first protective layer 131, the texture and the preparation approach of the protective layer in the prior art may be employed, however, the difference from the prior art lies in that the thickness of the first protective layer 131 is relatively small, in general 0.05-1 μm. In a specific encapsulation procedure of the embodiment, the encapsulation may be done by coating the first protective layer 131 of SiNₓ/SiO₂, on the OLED device by the approach of PECVD (plasma enhanced chemical vapor deposition).

In addition, the second protective layer 132 is only distributed in a corresponding area over a pixel, the requirement for its texture is the same as that of the existing protective layer, and when embodied in particular, the second protective layer 132 may be formed only in a corresponding area over a pixel by way of using a mask plate for occlusion; of course, in addition, the second protective layer 132 may also be formed by way of photolithography.

The texture of one of the first protective layer 131 and the second protective layer 132 described above is the silicon nitride or the silicon-oxygen-based material, or the textures of both the first protective layer 131 and the second protective layer 132 are the silicon nitride or the silicon-oxygen-based material.

The specific encapsulation method for the flexible display apparatus in the embodiment as shown in FIG. 5 may reduce the probability of the encapsulating film layer producing cracks, and improve the performance of flex resistance of the device; moreover, it does not need to improve greatly the existing preparation flow and thus is easily implemented. In particular, in the procedure of encapsulation, it is only necessary to prepare the original protective layer with a single layer film structure respectively by dividing it into two steps to a dual-layer film, wherein the first layer of film is the first protective layer 131 distributed continuously, which is the same as the existing preparation approach; and the second layer of film is the patterned second protective layer 132, and in preparation, a mask plate may be used for occlusion, or the photolithography may be used to form a pattern.

FIG. 6 shows a flow chart of an encapsulation method for the flexible display apparatus according to the second embodiment of the disclosure, which corresponds to the encapsulation structure of the flexible display apparatus as shown in FIG. 4. The method comprises: at step S201, on the cathode of the OLED device 12, forming a first film layer 134 with a dense film texture in a corresponding area over a pixel, which corresponds to a water oxygen barrier region 120; and at step S202, forming a second film layer 135 with a loose film texture in a gap between the first film layers 134, which corresponds to a multi-functional region 130.

At step S201, a layer of SiNₓ/SiO₂ with a dense film texture may be coated on the OLED device 12 by PECVD, and patterning may be done employing a mask plate for occlusion, to occlude a part (corresponding to a multi-functional region 130) which need not be covered with the first film layer 134 using a mask plate. In order to reduce the difference of the film thickness, the part occluded by the mask plate at step S201 is deposited a layer of SiNₓ/SiO₂ with a loose film texture by PECVD, which plays the role of stress blocking and further has the functions of sealing and planarization. The material of the second film layer 135 may also comprise a porous material, e.g., a porous material with the function of moisture absorption.

The above first film layer 134 may be of the silicon nitride or the silicon-oxygen-based material with a dense film texture; and the second film layer 135 may be of the silicon nitride or the silicon-oxygen-based material with a loose film texture. In preparation, a desired pattern may be obtained by using a mask plate for occlusion or photolithography. In addition, it needs to be noted that, the above-described first film layer 134 and the second film layer 135 may be of the same material, or also may be of different materials. If they are of the same material, the first film layer 134 and the second film layer 135 should be prepared respectively employing different processes (or the same process with different process parameters) to meet different demands for the film textures, and reduce the difference in the film thickness.

The encapsulation methods for the flexible display apparatuses in the embodiments as shown in FIGS. 5 and 6 solve the problem of easily producing cracks with the existing encapsulating film layer and improve the performance of flex resistance of the flexible display apparatuses by arranging a multi-functional region in the protective layer to cut off the expansion path of the stress of the film layer.

Except for forming a protective layer having a multi-functional region functioning to block the stress, the flows of preparation and encapsulation of the flexible display apparatuses are identical to the prior art, and the embodiments of the disclosure will not be described in detail again. For example, after the protective layer is produced, a protective film is also needed to be attached for protection to prevent the protective layer from being scratched. The way of attaching may be in the form of hard attached to hard and soft attached to hard, which is roughly the same as the prior art and will not be repeated here.

For a clear description, such a word as first, second, etc. is employed in the disclosure to conduct a category differentiation, however, the word first, second does not limit the disclosure in terms of number, and it is just an illustration of a preferred way. Obvious similar variations or relevant extensions occurring to the skilled in the art according to the disclosure all fall within the protection scope of the invention.

The individual embodiments in the specification are described using a progressive manner, identical or similar parts of the individual embodiments may be referred relative to each other, and each embodiment highlights its difference from other embodiments. Especially for an embodiment of a manufacture method, it is described relatively simply due to it corresponding to a respective apparatus embodiment, and as for its relevant parts reference may be made to the description of the parts of the apparatus embodiment.

What are described above are just specific embodiments of the disclosure, however, the protection scope of the disclosure is not limited thereto, and variations or alternatives easily occurring to any artisan familiar with the technical field within the technical scope disclosed by the disclosure should be encompassed within the protection scope of the disclosure. Therefore, the protection scope of the disclosure should be subject to the protection scope of the claims.

1. A flexible display apparatus comprising: an LED device, and a protective layer overlying a cathode of the OLED device, wherein the protective layer comprises a water oxygen barrier region and a multi-functional region, the multi-functional region has dual functions of a water oxygen barrier and stress blocking, and the thickness of the film layer in the multi-functional region is less than that of the film layer in the water oxygen barrier region, and/or the film texture in the multi-functional region is looser than that in the water oxygen barrier region.

2. The flexible display apparatus as claimed in claim 1, wherein the location of the multi-functional region corresponds to a spaced area between adjacent pixels, and the location of the water oxygen barrier region corresponds to a pixel area.

3. The flexible display apparatus as claimed in claim 1, wherein the protective layer comprises: a first continuously distributed protective layer and a second patterned protective layer, wherein the first protective layer completely covers the cathode of the OLED device, and the second protective layer is only distributed in the water oxygen barrier region.

4. The flexible display apparatus as claimed in claim 3, wherein the thickness of the first protective layer is 0.05-1 μm.

5. The flexible display apparatus as claimed in claim 3, wherein the texture of one of the first protective layer and the second protective layer is the silicon-nitrogen-based material or the silicon-oxygen-based material, or the textures of both the first protective layer and the second protective layer are the silicon-nitrogen-based material or the silicon-oxygen-based material.

6. The flexible display apparatus as claimed in claim 1, wherein the protective layer comprises: a first film layer with a dense film texture, only distributed in the water oxygen barrier region; and a second film layer with a loose film texture, only distributed in the multi-functional region.

7. The flexible display apparatus as claimed in claim 6, wherein the first film layer is of the silicon-nitrogen-based material or the silicon-oxygen-based material with a dense film texture; and the second film layer is of the silicon-nitrogen-based material or the silicon-oxygen-based material with a loose film texture.

8. An encapsulation method for a flexible display apparatus, the encapsulation method comprising: after the completion of a cathode of an OLED device, forming a protective layer comprising a water oxygen barrier region and a multi-functional region overlying the cathode of the OLED device,
wherein the multi-functional region has dual functions of a water oxygen barrier and stress blocking, and the thickness of the film layer in the multi-functional region is less than that of the film layer in the water oxygen barrier region, and/or the film texture in the multi-functional region is looser than that in the water oxygen barrier region.

9. The encapsulation method as claimed in claim 8, wherein the step of is forming a protective layer comprising a water oxygen barrier region and a multi-functional region overlying the cathode of the OLED device comprises:
forming a first protective layer continuously distributed and completely covering the cathode of the OLED device on the cathode of the OLED device; and
forming a second protective layer only distributed in a corresponding area over a pixel on the first protective layer,
wherein an area where the second protective layer is located constitutes the water oxygen barrier region, whereas an area in which only the first protective layer is distributed constitutes the multi-functional region.

10. The encapsulation method as claimed in claim 9, wherein the step of forming a second protective layer comprises: on the first protective layer, forming the second protective layer in a corresponding area over a pixel by using a mask plate.

11. The encapsulation method as claimed in claim 8, wherein the step of forming a protective layer comprising a water oxygen barrier region and a multi-functional region overlying the cathode of the OLED device may comprise:
forming a first film layer with a dense film texture in a corresponding area over a pixel on the cathode of the OLED device; and
forming a second film layer with a loose film texture in a gap between the first film layers,
wherein an area where the first film layer is located constitutes the water oxygen barrier region, whereas an area where the second film layer is located constitutes the multi-functional region.
